(19) United States
(12) Patent Application Publication
(10) Pub. No.: US 2003/0049373 A1
(43) Pub. Date: Mar. 13, 2003

(54) Apparatus for and method of applying a substance to a substrate

(76) Inventors: Johannes Hubertus Antonius Van De Rijdt, Eindhoven (NL); Olav Johannes Seijger, Eindhoven (NL); Arnoldus Johannes Martinus Joseph Ras, Eindhoven (NL)

Correspondence Address: U.S. Philips Corporation, 580 White Plains Road, Tarrytown, NY, 10591, US

(21) Appl. No.: 10/238,799

(22) Filed: Sep. 10, 2002

(30) Foreign Application Priority Data
Sep. 13, 2001 (EP) 01203463.3

(51) Int. Cl. C23C 16/00; B05D 1/00

(52) U.S. Cl. 427/248.1; 427/8; 118/712; 118/715

(57) ABSTRACT

The invention relates to an apparatus (1) for and a method of applying a substance (16), such as a solution containing an electroluminescent (EL) material or a suspension containing silver particles, to a substrate (7). The apparatus comprises a substrate carrier (5), a nozzle head (12) comprising at least one nozzle (12A) for ejecting the substance (16), and means (2,3,4) for moving the substrate carrier (5) and the nozzle head (12) with respect to each other. It further comprises a first imaging device (13) fixed relative to the nozzle head (12), a second imaging device (9), and one or more references (8) fixed relative to and positioned within the image field of the second imaging device (9). The mechanical link between the substrate (7) and the nozzle head (12) is thus substantially circumvented and inaccuracies originating from this link are avoided.

The invention relates to an apparatus for applying a substance. The substance may be a solution containing an electroluminescent (EL) material or a suspension containing silver particles.

The invention further relates to a method of applying a substance to a substrate, the method at least comprising the steps of placing the substrate on a substrate carrier and providing a nozzle head comprising at least one nozzle for ejecting the substance.

An example of such an apparatus and method is known from e.g. European patent application EP 880 303. This document describes the manufacture of an organic EL element, comprising the steps of forming pixel electrodes on a transparent substrate, forming partition walls between the pixel electrodes, and forming luminescent layers on the pixel electrodes and between the partition walls by means of an ink-jet device. Owing to the ink-jet device<quote “it is possible to carry out fine patterning in a simple manner and in a short time. Further, it is also possible to control easily and freely the luminescent characteristics such as color balance and brightness (luminance) by adjusting the thickness of the layer through adjustment of the discharge amount of the ink or by adjusting the ink concentration.” unquote>

A disadvantage of this prior art is that the precision with which the substance is applied by the prior art apparatus is not good enough.

Accordingly, it is an object of the present invention to facilitate a more accurate application of a substance to a substrate.

To this end, a first aspect of the invention provides an apparatus for applying a substance as defined in claim 1. A second aspect of the invention provides an apparatus for applying a substance as defined in claim 2. A third aspect of the invention provides an apparatus for applying a substance as defined in claim 13. A fourth aspect of the invention provides a method of applying a substance to a substrate as defined in claim 8. A fifth aspect of the invention provides a method of applying a substance to a substrate as defined in claim 9. Advantageous embodiments are defined in the dependent claims.

The crux of the invention is that the apparatus of the invention comprises an imaging device fixed relative to the nozzle head, and that the relative position between an ejected amount of the substance and the image field of the imaging device can be accurately determined. Subsequently, the imaging device can be used to accurately position the nozzle head relative to the substrate in order to accurately apply ink to the substrate.

In order to accurately determine said relative position, the apparatus of the invention comprises one or more references. Thus, the relative position between an ejected amount of the substance from a nozzle and the image field of the imaging device can be accurately determined, viz. by moving the nozzle head and imaging device to a first position for ejecting an amount of the substance near a reference, moving the nozzle head and imaging device to a second position for imaging the ejected substance and the reference. The relative position can be determined from the data concerning the trajectory between the first and the second position, and the data from the imaging device.

Alternatively, the relative position between an ejected amount of the substance from a nozzle and the image field of the imaging device can be accurately determined by applying two imaging devices, wherein a first imaging device is fixed relative to the nozzle head and wherein one or more references are positioned within an image field of the second imaging device. The position of a first imaging device with respect to the nozzle head and the nozzles can be accurately determined, viz. by moving the nozzle head in the image field of the second imaging device for ejecting an amount of the substance. The second imaging device can image the ejected substance and the one or more references for acquiring data concerning the relative position between the ejected amount of the substance from a nozzle and the one or more references. When the relative position between the image field of the first imaging device and the one or more references is known or is determined, the relative position between an ejected amount of the substance from a nozzle and the image field of the first imaging device can be accurately determined using the data from the second imaging device.

One way to determine the relative position between the image field of the first imaging device and the one or more references is to use two references wherein the distance and/or orientation between these two references is accurately known. A first reference is positioned within the image field of the second imaging device, and a second reference is positioned within the image field of the first imaging device when the nozzle head is in the image field of the second imaging device. The relative position between the image field of the first imaging device and the first reference can be accurately determined using the data from the first imaging device and the known distance between the first and the second reference.

If at least one reference is also within reach of the first imaging device, this reference can be imaged by both cameras, either simultaneously or successively, and a second reference, e.g. positioned in the image field of the first imaging device when the second imaging device is imaging the first reference, will not be necessary.

The use of two imaging devices has the advantage that the nozzles can be calibrated more rapidly, because this calibration can be performed without repositioning the nozzle head and the imaging device fixed relative to said nozzle head.

It is preferred that the reference extends vertically, i.e. in a direction having a component perpendicular to the substrate or the plane in which the substrate is to be placed, and that the first imaging device can be positioned in a plane above said reference, whereas the second imaging device is positioned beside the reference. By employing two imaging devices viewing the reference from different planes, it becomes possible to obtain three-dimensional data concerning the trajectory of the substance.

A method according to the present invention is characterized by an imaging device which is fixed relative to the nozzle head, and at least one of the nozzles is calibrated by:

moving the nozzle head and imaging device to a first position for ejecting an amount of the substance near the reference,

moving the nozzle head and imaging device to a second position for imaging the ejected substance and the reference.

The relative position between an ejected amount of the substance from a nozzle and the image field of the imaging device can be determined from the data concerning the trajectory between the first and the second position, and the data from the imaging device.

A further method according to the present invention is characterized in that a reference is imaged with a first imaging device which is fixed relative to the nozzle head and at least one of the nozzles is calibrated (simultaneously or subsequently) by ejecting an amount of the substance and simultaneously imaging the ejected substance and the same or a further reference with a second imaging device.

The invention further relates to an apparatus for applying an object or a substance to a substrate as defined in the preamble of claim 11 and is characterized in that at least one reference extends vertically, i.e. in a direction having a component perpendicular to the substrate or the plane in which the substrate is to be placed, and in that the first imaging device is positioned in a plane above said reference, whereas the second imaging device is positioned beside the reference. Use of a vertical reference is also advantageous in other applications where e.g. the trajectory of an electric component is complex (not straight) or variable.

For the sake of completeness, it is noted that international patent application WO 97/38567 relates to a method of and a placement machine for placing a component onto a substrate using two imaging devices and a reference plate comprising at least two markers. This method and machine may suffer from inaccuracies due to e.g. temperature changes of the reference plate and, more importantly, does not yield three-dimensional information.

The invention will now be explained in more detail with reference to the drawing in which an embodiment of the present invention is schematically shown.

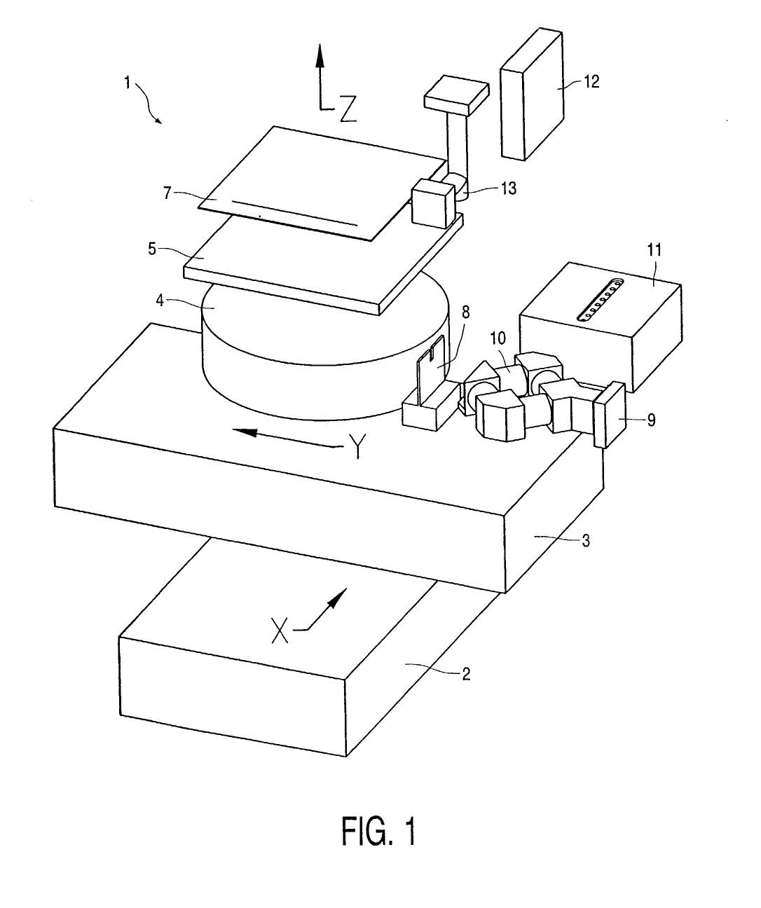

FIG. 1 is an exploded view of a printer according to the present invention.

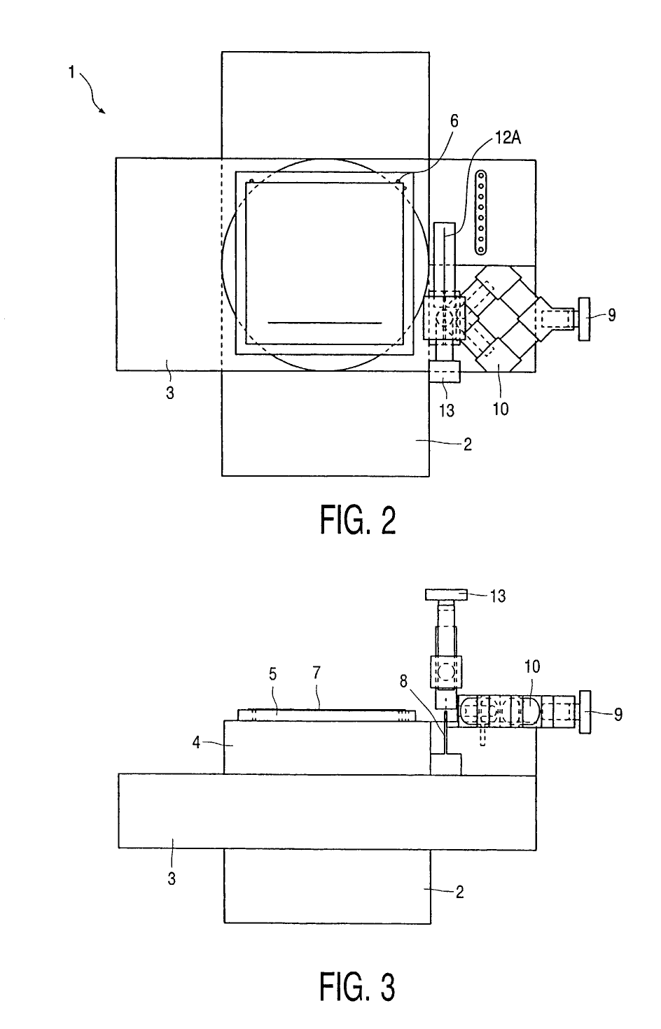

FIGS. 2 and 3 are a top and a side view, respectively, of the printer shown in FIG. 1.

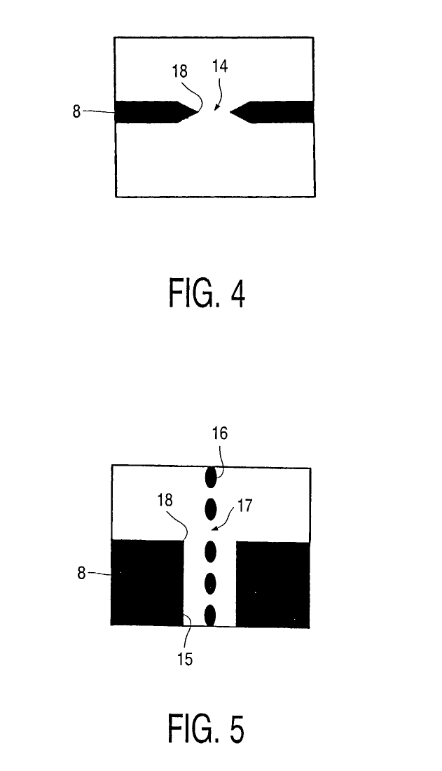

FIGS. 4 and 5 are a top and a side view, respectively, of a preferred reference for use in the printer shown in FIGS. 1 to 3.

FIGS. 1 to 3 show a printer, in this particular example an ink-jet printer 1 comprising a lower or X-direction slide 2 mounted on a frame (not shown) and an upper or Y-direction slide 3 mounted on top of the lower slide 2. A rotary table 4 (rotatable in the (pdirection) is mounted on the upper slide 3 and provided with a substrate carrier 5, which is thus movable in the X—, Y—, φ-directions and is provided with three reference-stubs 6 to facilitate exact and reproducible placement of a substrate 7 on the substrate carrier 5.

Furthermore, a vertical reference 8, a CCD (Charge Coupled Device) camera 9, hereafter referred to as ‘jet camera 9’, which comprises optics 10 and is positioned next to the reference 8, and a commonly known cap and clean device 11 are fixedly mounted on the upper slide 3 next to the rotary table 4. The optics 10 allow the imaging of the reference from two different directions at the same time, which are preferably 60 to 120 degrees apart, in this particular embodiment 90 degrees. Instead of using optics 10, it is also possible to employ two separate cameras or another suitable device.

A stationary nozzle head 12 comprising e.g. 256 nozzles arranged in a straight line 12A and a CCD camera 13, hereafter referred to as ‘substrate camera 13’, are attached to the above-mentioned frame (not shown) and fixed with respect to each other.

The reference 8, which is shown in more detail in FIGS. 4 and 5, is provided with a slot 14, which is flanked by two vertical side edges 15. As can be seen in FIG. 4, the side edges 15 are chamfered so as to provide clearly defined features and to facilitate the imaging from different directions by the optics 10 of substances or objects positioned behind the reference 8.

The substrate 7 in this example is intended for use in an electroluminescent (EL) segmented or matrix display device and comprises a transparent, e.g. glass, sheet which is provided with partitioning structures, such as parallel walls, or so-called bathtub structures. Droplets of a solution of an EL material can be deposited in such structures by means of inkjet printing, i.e. by means of the nozzle head 12.

The substrate 7 further comprises at least two, in this embodiment three marks (not shown) positioned at three different corners of the substrate 7. Such marks are common in the art and require no further explanation.

Information concerning the dimensions of the printer 1, the substrate 7, the reference 8 as well as information obtained by the cameras 9, 13, is stored in and processed by control unit (not shown), which also drives the above-mentioned slides 2, 3 and the rotary table 4.

The nozzles 12A are calibrated by imaging the reference 8 from above with the substrate camera 13 and subsequently positioning the nozzles 12A, one at a time, behind the slot 14 and in the mutually perpendicular image fields of the jet camera 9 and ejecting a series of droplets 16 from that particular nozzle 12A. The jet camera 9 and optics 10 measure the trajectory, i.e. any deviations in the X and Y-directions, as well as variations, such as a recurring pause 17, in the distance (in the Z-direction perpendicular to the X and Y-directions) between the droplets 16. At the same time, the position of the slides 2, 3 and the rotary table 4 are measured in known manner and stored in the control unit.

The exact position of the nozzles 12A and of the trajectory of the droplets 16 relative to the substrate camera 13 can thus be calculated by matching specific features, such as the two top ends 18 of edges 15, imaged from above by the substrate camera 13 with the same features 18 and the droplets 16 imaged by jet camera 9.

After imaging the droplets 16, the substrate camera 13 is positioned, by means of the slides 2,3, above a first and, subsequently, at least a second mark on the substrate 7. The position of these marks relative to those positions where the substance should be applied, in this case between the above-mentioned partitioning walls, is accurately known and stored in the above-mentioned controller unit. The unit calculates the relative position of the nozzles 12A with respect to the substrate 7 and directs the substrate 7, again by means of the slides 2,3, and if necessary also by means of the rotary table 4, to those positions where the droplets 16 are to be applied.

In the present example, several ways of application are suitable, including so-called line printing, where the nozzle head 12 moves parallel to the partitioning walls and so-called diagrammatic printing, where the nozzle head 12 moves perpendicular to the partitioning walls. In the former case, the lateral position and deviation of the nozzles 12A and the droplets 16, respectively, are significant, whereas in the latter case, the timing of ejecting the droplets 16 is important.

It is clear from this explanation that the mechanical link between the substrate and the nozzle head is substantially circumvented and inaccuracies originating from this link are avoided in a secure and relatively straightforward manner.

The invention is not limited to the above-described embodiments which can be varied in a number of ways within the scope of the claims. For instance, it is also possible to mount the substrate on a stationary frame and the nozzle head and second camera on a robot, which can move in the X and Y-directions and preferably also rotate relative to the substrate carrier. A stationary substrate is usually preferred if a low viscous substance is to be applied to the substrate as is the case in e.g. the manufacture of plasma displays where low viscous suspensions of silver particles need to be applied to a substrate.

1. An apparatus (1) for applying a substance (16) to a substrate, said apparatus (1) comprising a substrate carrier (5) for carrying the substrate, a nozzle head (12) comprising at least one nozzle (12A) for ejecting the substance (16), and means (2, 3, 4) for moving the substrate carrier (5) and the nozzle head (12) with respect to each other, characterized by an imaging device (13) fixed relative to the nozzle head (12), one or more references (8) positioned within reach of the imaging device (13), and simultaneous or subsequently within reach of the nozzle head for ejecting an amount of the substance near said references (8).

2. An apparatus (1) for applying a substance (16) to a substrate, said apparatus (1) comprising a substrate carrier (5) for carrying the substrate, a nozzle head (12) comprising at least one nozzle (12A) for ejecting the substance (16), and means (2, 3, 4) for moving the substrate carrier (5) and the nozzle head (12) with respect to each other, characterized by a first imaging device (13) fixed relative to the nozzle head (12), one or more references (8) positioned within reach of the nozzle head for ejecting an amount of the substance near said references (8), and a second image device (9) for imaging said references (8) and said ejected amount of the substance near said references (8).

3. An apparatus (1) as claimed in claim 2, wherein at least one reference (8) is also within reach of the first imaging device (13).

4. An apparatus (1) as claimed in claim 3, wherein the reference (8) extends vertically and wherein the first imaging device (13) can be positioned in a plane above said reference (8), whereas the second imaging device (9) is positioned beside the reference (8).

5. An apparatus (1) as claimed in claim 2, wherein the second imaging device (9,10) is arranged to image the reference (8) simultaneously from two different directions.

6. An apparatus (1) as claimed in claim 5, wherein said directions are 60 to 120 degrees apart.

7. An apparatus (1) as claimed in any one of claims 3 to 6, wherein the reference (8) comprises a slot (14) extending through its upper rim.

8. A method of applying a substance (16), such as a solution or a suspension, to a substrate (7), the method at least comprising the steps of placing the substrate (7) on a substrate carrier (5) and providing a nozzle head (12) comprising at least one nozzle (12A) for ejecting the substance (16), characterized by an imaging device (9) which is fixed relative to the nozzle head, and at least one of the nozzles (12A) is calibrated by:
moving the nozzle head and imaging device (9) to a first position for ejecting an amount of the substance (16) near the reference (8),
moving the nozzle head and imaging device (9) to a second position for imaging the ejected substance (16) and the reference (8).

9. A method of applying a substance (16), such as a solution or a suspension, to a substrate (7), the method at least comprising the steps of placing the substrate (7) on a substrate carrier (5) and providing a nozzle head (12) comprising at least one nozzle (12A) for ejecting the substance (16), characterized in that a reference (8) is imaged with a first imaging device (9) which is fixed relative to the nozzle head and at least one of the nozzles (12A) is calibrated by ejecting an amount of the substance (16) and simultaneously imaging the ejected substance (16) and the same or a further a reference (8) with a second imaging device (9).

10. A method as claimed in claim 9, wherein the reference (8) extends vertically and wherein the first imaging device (13) images said reference (8) from above and the second imaging device (9) images the reference (8) from one of its sides.

11. A method as claimed in claims 8 to 10, wherein data concerning the trajectory of the substance (16) ejected from the nozzle (12A) are measured.

12. A method as claimed in claim 11, wherein said nozzle (12A) and the substrate (7) are moved relative to each other and the trajectory data is employed to determine the moment when the substance (16) is ejected.

13. An apparatus (1) for applying an object or a substance (16) to a substrate (7), the apparatus comprising a substrate carrier (5), a nozzle head (12), means (2,3,4) for moving the substrate carrier (5) and the head (12) with respect to each other, a first imaging device (13) fixed relative to the head (12), a second imaging device (9), and one or more references (8) fixed relative to and positioned within the image field of the second imaging device (9), characterized in that at least one reference (8) extends vertically, and in that the first imaging device (13) is positioned in a plane above said reference (8), whereas the second imaging device (9) is positioned beside the reference (8).
